(19) United States
(12) Patent Application Publication
(10) Pub. No.: US 2005/0204239 A1
(43) Pub. Date: Sep. 15, 2005

(54) Method for testing semiconductor integrated circuit

(76) Inventors: Shinya Miyaji, Nara (JP); Osamu Ichikawa, Osaka (JP)

Correspondence Address: MCDERMOTT WILL & EMERY LLP, 600 13TH STREET, N.W., WASHINGTON, DC, 20005-3096, US

(21) Appl. No.: 11/038,493

(22) Filed: Jan. 21, 2005

(30) Foreign Application Priority Data
Jan. 21, 2004 (JP) 2004-013535
Jan. 14, 2005 (JP) 2005-008210

(51) Int. Cl. G01R 31/28; G06F 11/00

(52) U.S. Cl. 714/738

(57) ABSTRACT

An inventive method is a method for testing a semiconductor integrated circuit that includes a memory circuit provided between a first storage element and a second storage element. The inventive method includes the steps of: (a) initializing the memory circuit; (b) supplying a test pattern to the first storage element; (c) supplying a memory access signal, which corresponds to the test pattern supplied to the first storage element, to the memory circuit through a path that is used in normal operation; (d) capturing a value output from the memory circuit in response to the memory access signal, into the second storage element through a path that is used in normal operation; and (e) comparing the value captured into the second storage element with an expected value.

### CROSS-REFERENCE TO RELATED APPLICATION

This application claims priority under 35 U.S.C. § 119 on Patent Application Nos. 2004-13535 filed in Japan on Jan. 21, 2004, and No. 2005-8210 filed in Japan on Jan. 14, 2005, the entire contents of which are hereby incorporated by reference.

### BACKGROUND OF THE INVENTION

The present invention relates to methods for testing actual operation of a memory interface (input terminal/output terminal).

An operation test of a semiconductor integrated circuit having a memory and logic circuits generally includes two tests: a test of the logic circuits and a test of the memory. Typical tests of a logic circuit are logic BIST and scan test, while typical tests of a memory are memory BIST and memory test performed using a tester. In a test of a logic circuit, wiring or transistors are inspected for defects. On the other hand, in a test of a memory, not only a test similar to the logic circuit test is performed, but relation between values retained in adjacent memory cells and read/write sequences are tested.

(Memory Interface Test using Memory BIST)

Memory BIST is one of methods for performing at-speed test of a memory (for methods using memory BIST, see non-patent document 1 and FIG. 12.3.)

FIG. 12(a) illustrates an exemplary semiconductor integrated circuit composed of a memory, logic circuits which access the memory, and a built-in self-test circuit for testing the memory. In FIG. 12(a), a logic circuit 1202 writes data into a memory 1201 in normal operation mode. A logic circuit 1203 captures output data from the memory 1201 in normal operation mode. A built-in self-test circuit (memory BIST) 1207 generates a specific pattern for the memory 1201 and compares data read from the memory 1201 with an expected value to determine whether or not the memory 1201 operates properly. A selector 1209 selectively inputs to the memory 1201 a signal 1211 from the logic circuit 1202 or a signal 1215 from the memory BIST 1207. At the time the memory 1201 is tested, the signal 1215 from the memory BIST 1207 is selected by the selector 1209 and a specific pattern is applied from the memory BIST 1207 to the memory 1201. An output response 1213 produced from the memory 1201 in reply to the applied pattern is captured into the logic circuit 1203, while the output response 1213 goes through a branched signal-line 1214 to be captured into the memory BIST 1207 where the output response 1213 is compared with an expected value to determine whether or not there is a detect in the memory 1201.

As described above, in the test of the memory 1201 using the memory BIST 1207, in order to input the test pattern into the memory 1201, the selector 1209 is inserted in the path that is used to access the memory 1201 during normal operation, thereby providing another path from the memory BIST 1207, through which another path the pattern is applied to the memory 1201. Also, provided for the output from the memory 1201 are the path through which the output from the memory 1201 is captured into the logic circuit 1203 in normal operation, and another path, through which the branched output from the memory 1201 is captured into the memory BIST 1207. That is, the output from the memory 1201 is compared with an expected value using the path that is different from the path used in normal operation.

FIG. 12(b) is an exemplary circuit in which a pseudo-random pattern generation circuit (PRPG) and a compression circuit (MISR) are used to perform a built-in self test in the semiconductor integrated circuit that includes a memory (for methods for memory bypass, see non-patent document 1 and FIG. 12.6.)

In a test in which a compression circuit is used, an output response produced in reply to an applied test pattern is captured into the compression circuit, and a value finally left in the compression circuit is compared with a value calculated in advance, to determine whether or not there is a defect in the target circuit subjected to the test. If an indeterminate value (x) is input to the compression circuit, a value within the compression circuit is destroyed, so it is necessary to design the test circuit in such a manner that no indeterminate value is transmitted to the compression circuit from the test target circuit.

In FIG. 12(b), a random pattern from a pseudo-random pattern generation circuit 1205 is applied to a logic circuit 1202 via a signal line 1226. In response to the random pattern, the logic circuit 1202 performs a write operation or a read operation to or from the memory 1201 via a signal line 1221, while an output value from the logic circuit 1202 is captured into a compression circuit 1206 via a signal line 1228. The output response resulting from the random pattern that has been input to the logic circuit 1202 causes the memory 1201 to output data, which is an indeterminate value, because the memory 1201 outputs an indeterminate value during a test. In order to prevent the indeterminate value from being captured into the compression circuit 1206, a selector 1210 is disposed at the output side of the memory 1201 so as to select, based on a mode signal, a bypass signal, which is the input signal 1221 that has bypassed the memory 1201, whereby a determinate value is input to the logic circuit 1203. Also, a flip-flop 1208 is inserted in a bypass signal line 1225 so that the observability of the bypass signal and the controllability of the logic circuit 1203 are increased so as to raise the fault coverage. Upon receipt of an input from the pseudo-random pattern generation circuit 1205 and a signal 1223 that has bypassed the memory 1201, the logic circuit 1203 produces an output response, which is captured into the compression circuit 1206 through a signal line 1229.

In this manner, when the test of the semiconductor integrated circuit that includes the memory 1201 is tested using the compression circuit 1206, the test is performed by disposing the selector 1210 at the output side of the memory 1201 so that the value that has bypassed the memory 1201 is selected in order to prevent the indeterminate value output from the memory 1201 from being captured into the compression circuit 1206.

(Memory Interface Test Using Scan Test)

Another method for conducting at-speed testing of memory interface is a test method using scan testing, which is a test of logic circuits (for techniques using scan testing, see non-patent document 2.)

FIG. 13 illustrates a semiconductor integrated circuit composed of a memory and logic circuits that access the memory. In FIG. 13, a storage element 1301 performs a write to a memory 1303 via a combinational circuit 1302 in normal operation mode. A storage element 1304, on the other hand, captures output data from the memory 1303 via a combinational circuit 1305 in normal operation mode. When values at terminals SE are “0”, the storage elements 1301 and 1304 capture values at terminals D on the edges of a clock CK, while at the same time they output the respective captured values to terminals Q. When the values at the terminals SE are “1”, on the other hand, they capture values at terminals SI on the edges of the clock CK, while at the same time they output the respective captured values to terminals SO. A tester sets the values at the terminals SE to “1”, and establishes values at the storage elements 1301 and 1304 by a scan shift operation in which values are sequentially transmitted from the terminals SI in accordance with the clock, while the tester sequentially reads the values at the storage elements 1301 and 1304 from the terminals SO to compare these read values with expected values, thereby testing the memory interface.

If a storage element, such as a memory, that is not capable of shift operation is included, the value of the memory cannot be directly determined by shift operation. The value has to be established in an indirect manner; the value is first set at a storage element capable of shift operation by a shift operation and then captured into the memory by a normal operation. This process requires a partial scan test technique, which is more sophisticated than full a scan test technique used for a circuit in which all of the components are scan storage elements. Thus, this process tends to require more test patterns.

Non-Patent Document 1

“A Designer's Guide to Built-in Self-Test” by Chrles E. Stroud, Kluwer Academic Publishers, ISBN 1-4020-7050-0, Chapter 12.2 RAM BIST Architectures, FIG. 12.3, Chapter 12.4 Bypassing Regular Structures During BIST, FIG. 12.6

Non-Patent Document 2

“FASTSCAN AND THE ATPG PROCUCT FAMILY DATASHEET” by Mentor Graphics, http://www.mentor.com/dft/fastscan_ds.pdf

In a case where memory BIST is used to test the actual input and output operation of a memory, a test pattern is applied to the memory by way of a memory BIST path, which is different from a normally used path. Also, an output signal from the memory, which is input to a logic circuit that uses the output signal from the memory, is branched, and an expected value comparison circuit in the memory BIST circuit determines whether there is a defect within the memory. Therefore, while the memory BIST is being performed, the test pattern is applied to the memory and the output signal is captured from the memory through the paths that are different from the paths used during normal operation, which means that the actual input/output operation of the memory cannot be tested using the paths used during the actual operation.

In some cases, to overcome this problem, in addition to verification of operation of a memory device performed by conducting memory BIST or other memory test, actual operation paths are verified by preparing a test pattern of normal operation. In these cases, however, the normal operation test pattern is prepared manually, such that a problem arises in that the number of semiconductor-integrated-circuit design process steps increases. Furthermore, if combinational circuits present between the memory and the storage elements become more complicated, it actually becomes difficult to design the normal operation test pattern. Moreover, since the verification using logic BIST or scan test and the verification using the normal operation test pattern are performed with separate EDA tools, the process of calculating fault coverage, which indicates how perfect the test is, becomes complicated.

In a case where a semiconductor integrated circuit including a memory is tested using a compression circuit, a selector is disposed at the output side of the memory in order to prevent an indeterminate value from being captured into the compression circuit, such that a signal having a determinate value that has bypassed the memory is selected during the test. Due to this, an output signal from the memory is not used and a signal written from the normal logic into the memory is not read from the memory output during the test. Consequently, it is not possible to test whether the write operation and the read operation to and from the memory are performed properly.

On the other hand, in the memory-interface testing method using scan testing, it is possible to solve the problem that actual operation cannot be tested and the problems about the actual operation test-pattern preparation and the complicated fault-coverage calculation. However, this method adopts a partial scan test technique, in which storage elements that correspond to addresses and write signals to the memory within the logic circuit are set by shift operation before values for the memory are established. Thus, the establishment of the values for the memory, which can be done in one cycle in actual operation, takes a considerable amount of time. For example, in a memory of 256 Kbytes/32-bit words, an address signal of the memory has 16 bits and the shift operation alone thus requires 16 or more cycles, resulting in a long test time which is equal to, or more than, 16 times the time required for the memory-value establishment in actual operation. In a case where no bypass circuits are prepared, all of the memory regions need to be initialized during logic BIST, so this case is actually impossible.

### SUMMARY OF THE INVENTION

It is therefore an object of the present invention to provide a test method which enables an actual operation test of input and output signals into and from a memory.

An inventive test method is a method for testing a semiconductor integrated circuit that includes a memory circuit provided between a first storage element and a second storage element. The inventive method includes the steps of: (a) initializing the memory circuit; (b) supplying a test pattern to the first storage element; (c) supplying a memory access signal, which corresponds to the test pattern supplied to the first storage element, to the memory circuit through a path that is used in normal operation; (d) capturing a value output from the memory circuit in response to the memory access signal, into the second storage element through a path that is used in normal operation; and (e) comparing the value captured into the second storage element with an expected value.

In the inventive method, the semiconductor integrated circuit preferably further includes a pseudo-random pattern generation circuit and a compression circuit; in the step (b), a random pattern produced from the pseudo-random pattern generation circuit is preferably supplied to the first storage element as the test pattern; and in the step (e), the value captured into the second storage element is preferably compressed by the compression circuit and a signal resulting from the compression is preferably compared with the expected value.

In the inventive method, the first and second storage elements preferably are storage elements capable of scanning; in the step (b), the test pattern is preferably supplied to the first storage element by a shift operation; and in the step (e), the value captured into the second storage element is preferably read by a shift operation, and the read value is preferably compared with the expected value.

In the inventive method, the memory circuit is preferably a multiport memory having a write port and a read port separately; and the semiconductor integrated circuit preferably further includes an address conversion circuit, which is provided between the first storage element and the memory circuit and prevents, during a test, a write and a read from being performed simultaneously to and from an identical address in the write and read ports of the memory circuit.

In the inventive method, the semiconductor integrated circuit preferably further includes an address conversion circuit, which is provided between the first storage element and the memory circuit and limits accesses made to the memory circuit in the steps (c) and (d) to a given region; and in the step (a), of regions in the memory circuit, the region limited by the address conversion circuit is preferably initialized.

In the inventive method, in the step (b), a pattern for performing a write to the memory circuit is preferably supplied to the first storage element as the test pattern.

In the inventive method, the semiconductor integrated circuit preferably further includes a write inhibit circuit, which is provided between the first storage element and the memory circuit and inhibits any writes to the memory circuit in the steps (b) through (e).

In the inventive method, the initialization of the memory circuit in the step (a) is preferably performed in a memory test.

In the inventive method, the step (a) preferably includes: the step (a1) of performing a memory test, and the step (a2) of establishing a value for a region in the memory circuit.

In the inventive method, the semiconductor integrated circuit preferably further includes a memory BIST circuit for testing the memory circuit, and the memory test is preferably performed using the memory BIST circuit.

In the inventive method, the memory circuit preferably includes a non-volatile region, and in the step (a), an initial value is preferably stored in the non-volatile region.

In the inventive method, in the step (a), of test sequences prepared for a combinational circuit, whose start point includes a data output terminal of the memory circuit and whose end point is a storage element reachable by a signal which is output from the data output terminal of the memory circuit, a test sequence assigned to the data output terminal is preferably used as a value to which the memory circuit is initialized.

In the inventive method, process steps performed in the steps (b) through (e) are preferably performed at an actual operation speed of the semiconductor integrated circuit.

The inventive method preferably further includes the steps of: (f) modeling the memory circuit into a combinational sequential circuit, and (g) generating a test pattern using the modeled memory circuit, wherein in the step (b), the test pattern generated in the step (g) is preferably supplied to the first storage element.

The inventive method preferably further includes the steps of: (f) modeling the memory circuit into a combinational sequential circuit, and (g) generating, using the modeled memory circuit, a test pattern that does not include a write to the memory circuit, wherein in the step (b), the test pattern generated in the step (g) is preferably supplied to the first storage element.

In the inventive method, in the step (f), the memory circuit is preferably modeled into a combinational circuit.

In the inventive test method, a memory-circuit initialization process step is provided to initialize the memory circuit, so that an indeterminate value is not output by a read operation from the memory circuit in a later step in the test. Then, an output value from the memory circuit is captured through a path used in normal operation, and the captured value is compared with an expected value, whereby it becomes possible to conduct an actual operation speed test between the output from the memory circuit and the normal logic (including the second storage element) that receives that value. Even in a state in which no write is performed to the memory circuit, it is possible to test the logic circuits (including the first storage element and/or the second storage element) disposed before and after the memory circuit, by performing a read from the memory circuit.

In the case of a multiport memory, similar effects are also expected, if an address conversion circuit is added, which prevents, during a test, a write and a read from being performed simultaneously to and from an identical address in the write and read ports of the multiport memory.

Also, a value is written from the logic circuit (including the first storage element) to the memory circuit in accordance with a test pattern that has been input to the logic circuit (including the first storage element) as a random pattern, and the written value is read and the value read from the memory circuit is captured into the logic circuit (including the second storage element), whereby it becomes possible to test the write and read to and from the memory circuit at the actual operation speed using the paths used in normal operation.

Furthermore, a memory-circuit initialization process step is provided to initialize the memory circuit, such that a value for testing the logic circuits (including the first storage element and/or the second storage element) that are forward- and backward-connected to the memory circuit does not need to be established in the memory circuit by scan testing, thereby reducing the test time.

Moreover, if the initialization of the memory circuit is performed only in a limited region, setting of the memory circuit is omitted, which enables the test time to be reduced, while at the same time if a circuit that limits accesses made during a BIST test or a scan test only to the initialized region is added, restrictions during generation of test sequences are eliminated, thereby making it easy to generate the test sequences.

If a pattern for performing a write to the memory during a BIST test or a scan test is applied, it is possible to establish in the memory circuit a value for testing the logic circuits (including the first storage element and/or the second storage element) that are forward- and backward-connected to the memory circuit, and then test those logic circuits, irrespective of a value established in the memory circuit before the BIST test or the scan test.

Also, if the memory circuit is initialized by a memory test, setting of the memory circuit can be omitted, thereby reducing the test time.

Moreover, in addition to the value for the memory circuit established in the memory test, if the memory circuit is appropriately initialized only to the extent necessary for testing the logic circuits that are forward- and backward-connected to the memory circuit, test time for the memory circuit setting can be reduced, while at the same time it is possible to test the logic circuits that are forward- and backward-connected to the memory circuit without performing a write to the memory circuit.

Also, if an initial value for the memory circuit is stored in a non-volatile region such as a RAM or ROM, test time for memory setting becomes unnecessary, while at the same time, for the non-volatile memory, such as a ROM, it becomes possible to test logic circuits that are forward- and backward-connected to the memory circuit.

If an initial value for the memory circuit is determined with a test pattern generation tool, it becomes possible to easily determine a set value for the memory circuit according to the purpose of the test, such as stack fault detection or delay fault detection, even if the logic circuits that are forward- and backward-connected to the memory circuit become complicated.

Also, if a test is conducted at an actual operation frequency, testing of the memory interface at the actual operation speed becomes possible.

In the inventive test method, the memory circuit is initialized before a BIST test or a scan test, and the memory circuit is modeled into a combinational sequential circuit in the semiconductor integrated circuit in which no write is performed during the BIST test or scan test. This simplifies the logic of the memory circuit, while allowing the time required for test pattern generation to be reduced.

Also, if generation of a write operation pattern is prohibited in test pattern generation, it is not necessary to incorporate a write inhibit circuit for inhibiting a write to the memory during a BIST test or a scan test, thereby enabling the costs of the semiconductor integrated circuit to be reduced.

If the clock applied to the memory circuit is a delay clock which is delayed behind the clock applied to the logic circuits that are forward- and backward-connected to the memory circuit, the memory circuit can be modeled into a combinational circuit and it is possible to generate a test pattern with a conventional full scan test technique. Moreover, in the case of a latest scan test tool, it is also possible to reduce the time necessary for test pattern generation.

### BRIEF DESCRIPTION OF THE DRAWINGS

FIG. 1 is a block diagram illustrating an exemplary semiconductor integrated circuit according to a first embodiment of the present invention.

FIG. 2 is a flow chart indicating how to conduct a memory-interface actual-operation test according to the first embodiment of the present invention.

FIG. 3 is an operation wave-form chart of the semiconductor integrated circuit shown in FIG. 1.

FIG. 4 is a block diagram illustrating an exemplary semiconductor integrated circuit which includes a memory access circuit.

FIG. 5 is a block diagram illustrating an exemplary semiconductor integrated circuit that includes a dual port memory.

FIG. 6 is block diagram illustrating an exemplary semiconductor integrated circuit according to a second embodiment of the present invention.

FIG. 7 is a flow chart indicating how to conduct a memory-interface actual-operation test according to the second embodiment of the present invention.

FIG. 8 is a view indicating a flow for determining initial values for a memory according to the second embodiment of the present invention.

FIG. 9 is a view indicating the logic of a memory modeled into a combinational circuit according to the second embodiment of the present invention.

FIG. 10 shows a block diagram illustrating an exemplary semiconductor integrated circuit, and a view indicating the logic of a memory modeled into a combinational sequential circuit, according to the second embodiment of the present invention.

FIG. 11 is a block diagram illustrating an exemplary semiconductor integrated circuit that has a memory in which only a specific region is initialized.

FIG. 12 is a block diagram illustrating an exemplary conventional semiconductor integrated circuit.

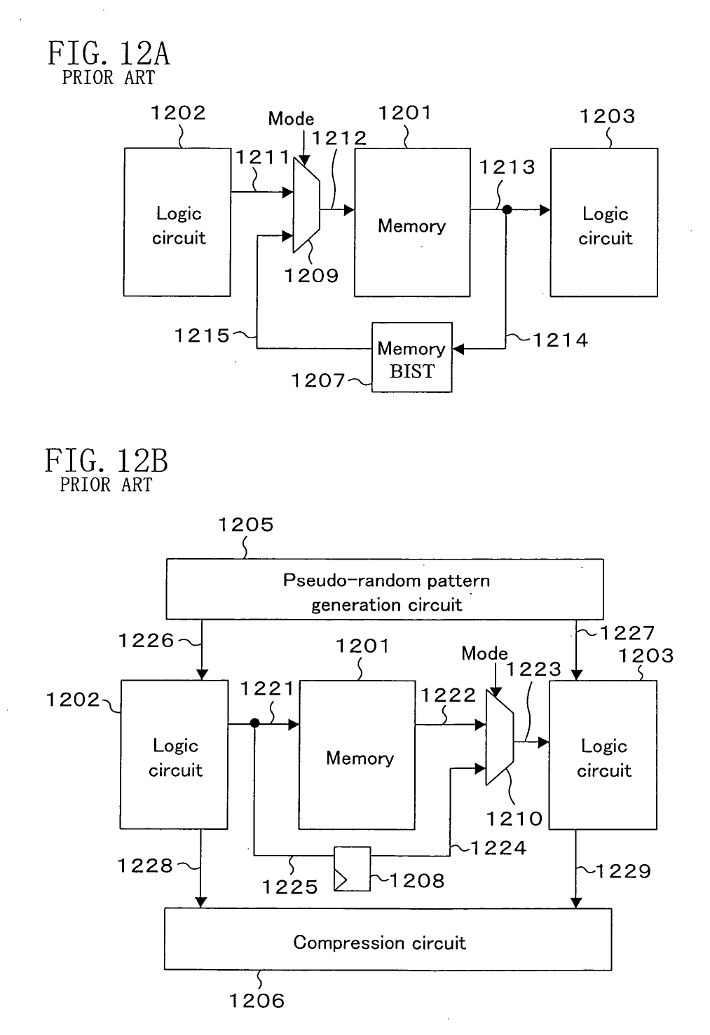

FIG. 13 is a block diagram illustrating an exemplary semiconductor integrated circuit in which a memory interface test is conducted by a conventional scan test.

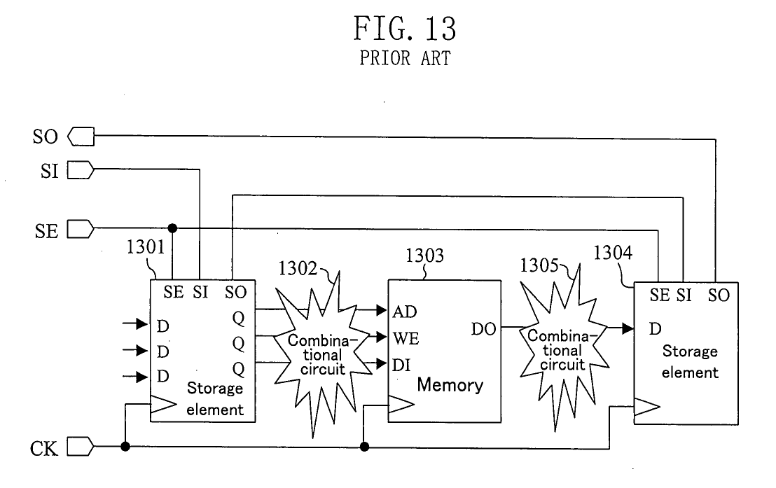

### DESCRIPTION OF THE PREFERRED EMBODIMENTS

Hereinafter, embodiments of the present invention will be described in detail with reference to the accompanying drawings. In the figures, the same or equivalent components are denoted by the same reference numerals, and descriptions thereof will not be repeated.

### First Embodiment

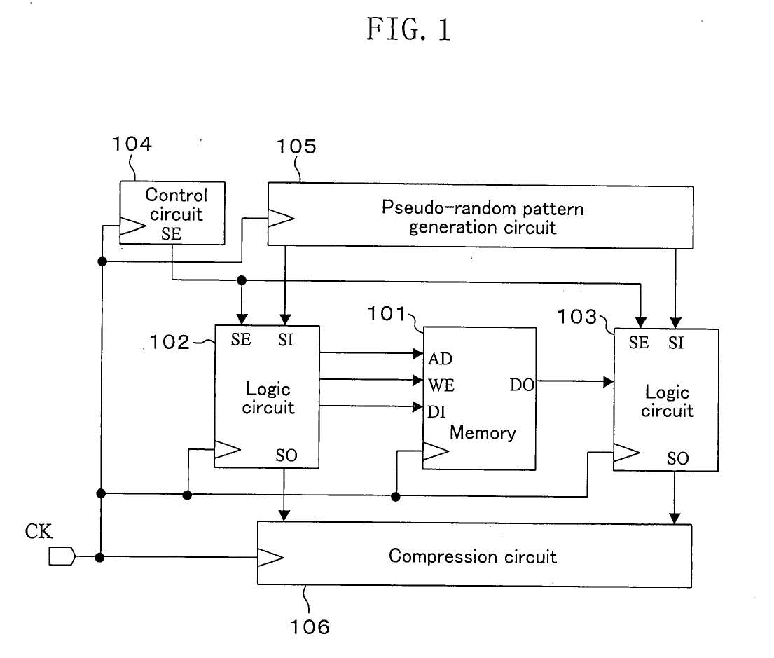

FIG. 1 is an exemplary semiconductor integrated circuit according to a first embodiment of the present invention. In the first embodiment, at-speed test of the interface (input and output) of a memory 101 included in the semiconductor integrated circuit shown in FIG. 1 will be discussed. The memory 101 is controlled from a logic circuit 102 and an output from the memory 101 is captured into a logic circuit 103. Each of the logic circuits 102 and 103 is of a scan test design and includes scan flip-flops and a combinational circuit portion, with the scan flip-flops forming a scan chain and including scan-in terminals SI, scan-out terminals SO, and scan-enable terminals SE. A pseudo-random pattern generation circuit 105 applies a pseudo-random pattern to the SI terminals of the logic circuits 102 and 103. A compression circuit 106 captures, from the SO terminals, output responses produced from the logic circuits 102 and 103 in reply to the pseudo-random pattern, and then compresses these values to generate signatures. A control circuit 104 controls the logic circuits 102 and 103.

A clock signal CK is a clock signal for the memory 101 and other blocks. A scan-enable signal SE is applied from the control circuit 104 to the logic circuits 102 and 103. When the value of the scan-enable signal SE is “1”, a shift operation is performed, and when the value of the scan-enable signal SE is “0”, a capture operation is performed.

An address signal AD, a write-enable signal WE, and a data-input signal DI of the memory 101 are signals that are applied from the logic circuit 102 to the memory 101 as a result of the input, into the logic circuit 102, of the pattern generated in the pseudo-random pattern generation circuit 105. When the write-enable signal WE is “0”, data is written into the memory 101, and when the write-enable signal WE is “1”, data is read from the memory 101. A data-output signal DO of the memory 101 is a value which is read according to a signal applied to the memory 101 and the read value is captured into the logic circuit 103 during a capture operation.

The application, to the logic circuit 102, of the pseudo-random pattern generated in the pseudo-random pattern generation circuit 105 causes the logic circuit 102 to access the memory 101 in response to the pseudo-random pattern, which results in the application of the data output value produced from the memory 101 to the logic circuit 103. Output responses produced from the logic circuits 102 and 103 in reply to these inputs are compressed and captured by the compression circuit 106, where signatures are created. The values stored in the compression circuit 106 are compared with expected values obtained in advance, whereby it is possible to determine whether or not there are failures in the logic circuits 102 and 103 and the memory 101.

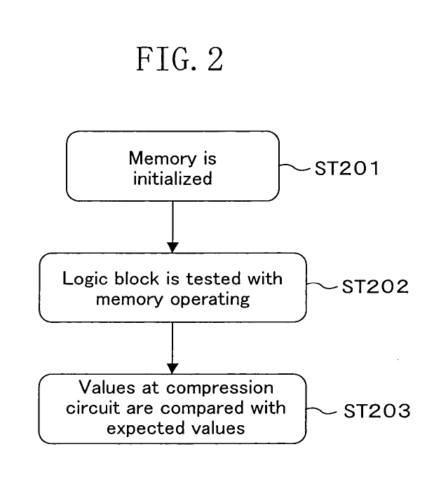

FIG. 2 is a flow chart indicating how to conduct the memory-interface actual-operation test according to the first embodiment of the present invention.

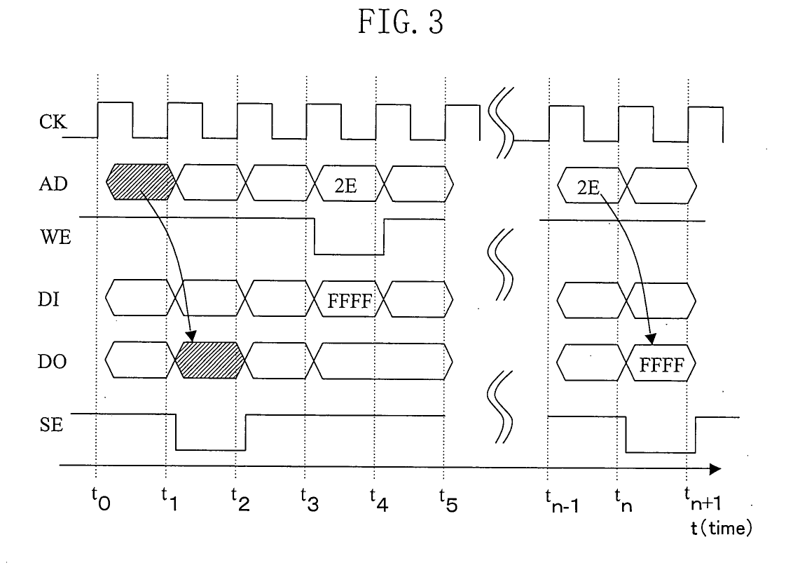

In step ST201, the memory 101 of FIG. 1 is initialized. This initialization is realized by making the logic circuit 102 operate to perform a write operation to the memory 101. After the completion of the initialization of the memory 101, in step ST202, the logic circuit block is tested with the memory 101 operating. The operation performed in step ST202 will be explained with reference to a wave-form chart shown in FIG. 3 by way of example.

(Testing of Actual-Operation of Path from Memory Output to Normal Logic)

On the rising edge of the clock CK at time t0, an address signal AD to the memory 101 is generated by the logic circuit 102 according to a test pattern from the pseudo-random pattern generation circuit 105 (the shadowed portion for AD in FIG. 2). The address signal AD produced at time t0 is captured into the memory 101 on the rising edge of the clock CK at time t1. At this time, since the value of the write-enable signal WE is 1, data is read from the memory 101 (the shadowed portion for DO in FIG. 2). The memory 101 already initialized in step ST201 does not output an indeterminate value as the data-output signal DO but outputs as the data-output signal DO a determinate value written in the memory 101 as a result of the initialization thereof.

On the rising edge of the clock CK at time t2, the scan-enable signal SE is 0, so the value (the shadowed portion for DO in FIG. 2) read from the memory 101 is captured into the logic circuit 103 through a path used in normal operation. The captured value is taken into the compression circuit 106 via the SO terminal of the logic circuit 103 after time t3 in a shift state in which the scan-enable signal SE is 1.

(Testing of Actual Operation of Path from Normal Logic to Memory Input)

On the rising edge of the clock CK at time t3, the logic circuit 102 applies signals to the memory 101 according to a test pattern from the pseudo-random pattern generation circuit 105. In the example of FIG. 3, an address value of “2E”, a data input value of “FFFF” and a write-enable signal value of “0” are applied to the memory 101 from the logic circuit 102. On the rising edge of the clock CK at time t4, the write-enable signal value “0”, the address value “2E”, and the data input value “FFFF” are captured into the memory 101, and the data value “FFFF” is written from the logic circuit 102 into the memory 101 at the address “2E” through a path used in normal operation.

After time t4, similarly, signals are applied from the logic circuit 102 to the memory 101 in accordance with a test pattern from the pseudo-random pattern generation circuit 105, and based on these signal values applied to the memory 101, data-write/data-read into/from the memory 101 is performed.

The address value “2E”, which has been written into the memory 101 from the logic circuit 102 at time t4 in accordance with the test pattern from the pseudo-random pattern generation circuit 105, is re-generated at time tn-1, and then at time tn, the write-enable signal WE becomes 1, whereby the value “FFFF”, which has been written into the memory 101 at time t4, is output from the corresponding address at time tn. At this time, if the scan-enable signal SE changes from 1 to 0, the logic circuit performs a capture operation at the next time tn+1, causing the value “FFFF” read from the memory 101 to be captured into the logic circuit 103 via a path used in normal operation. The captured value is then taken into the compression circuit 106 after time tn+1 via the SO terminal of the logic circuit 103 in a shift state in which the scan-enable signal SE is 1.

(Testing of Logic Circuit Portion)

A random pattern generated in the pseudo-random pattern generation circuit 105 is applied as a test input to the logic circuit 102. In response to the random pattern applied to the logic circuit 102, the logic circuit 102 accesses the memory 101 to cause a signal to be read from the memory 101 and then input to the logic circuit 103. This signal and the random pattern generated in the pseudo-random pattern generation circuit 105 are applied to the logic circuit 103 as a test input. Output responses produced from the logic circuits 102 and 103 according to these test inputs are captured into the compression circuit 106 for compression. The compressed values are compared with expected values calculated in advance, whereby the logic circuits 102 and 103 are also tested.

When the memory 101 is made to operate and the test of the logic block is completed, the process proceeds to step ST203, in which the values at the compression circuit 106 are compared with the expected values.

As described above, in the first embodiment, the memory initialization step ST201 provided for the initialization of the memory 101 prevents an indeterminate value from being output by a read operation from the memory 101. This permits the output value DO from the memory 101 to be captured through a path used in normal operation, and therefore it is possible to test, using the compression circuit 106, the actual operation speed between the output DO of the memory 101 and the normal logic that receives that value. Also, a value is written from the logic circuit 102 into the memory 101 in accordance with a test pattern that has been input to the logic circuits 102 and 103 as a random pattern, and the written value is read from the memory 101 and the read value is captured into the logic circuit 103, whereby it becomes possible to test the write and read operations to and from the memory 101 at the actual operation speed using the paths used in normal operation.

In the first embodiment, the pseudo-random pattern generation circuit 105 is used to generate test patterns. However, even if the pseudo-random pattern generation circuit 105 is not used and a test pattern is input from an external terminal, effects similar to those obtained in the first embodiment are achievable.

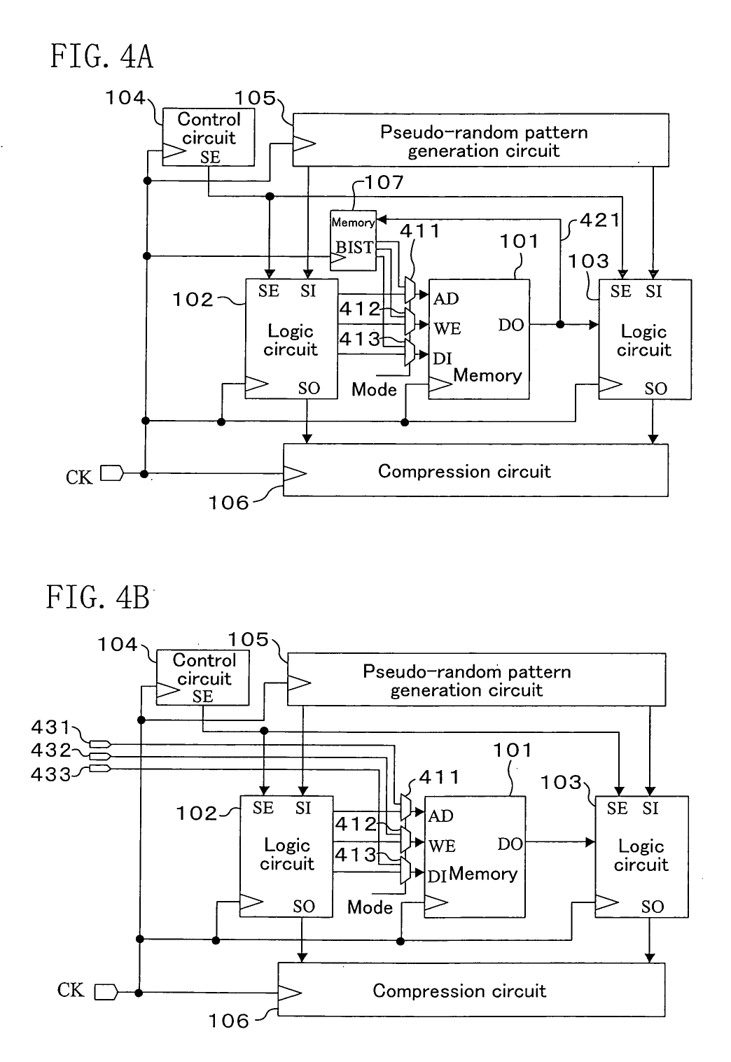

In the first embodiment, in step ST201, the logic circuit 102 is made to operate to perform a write to the memory 101, whereby the memory 101 is initialized. However, as shown in FIG. 4(a), in the case of a circuit configuration in which a memory BIST portion 107 for testing a memory 101 is built in, the memory BIST portion 107 is activated in step ST201 so that a specific pattern is input from the memory BIST portion 107 to the memory 101 by way of selectors 411, 412 and 413, which results in the initialization of the memory 101. Even in this case, effects similar to those obtained in the first embodiment are achieved.

Also, even if the memory initialization step ST201 is performed as shown in FIG. 4(b), that is, even if the memory 101 is initialized by putting the memory 101 in isolation, in which a pattern is directly input to the memory 101 from external terminals 431, 432 and 433 via selectors 411, 412, and 413, effects similar to those of the first embodiment are attained.

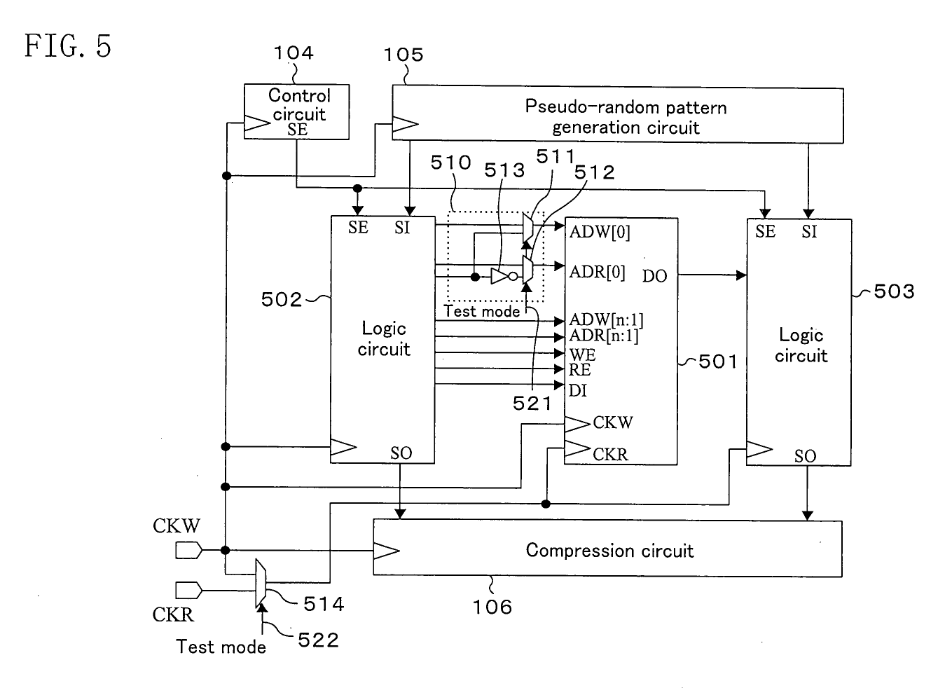

Furthermore, as shown in FIG. 5, in the case of a semiconductor integrated circuit including a dual port memory 501, an address conversion circuit 510 for address conversion is provided to prevent ADW, a write address, and ADR, a read address, from having the same value so that a write operation and a read operation do not occur simultaneously at the same address during a test. This prevents an indeterminate value from being output from the dual port memory 501 in response to a signal produced from a logic circuit 502 that accesses the dual port memory 501, whereby an output DO having a determinate value is captured into a logic circuit 503. Therefore, effects similar to those of the first embodiment are obtainable.

### Second Embodiment

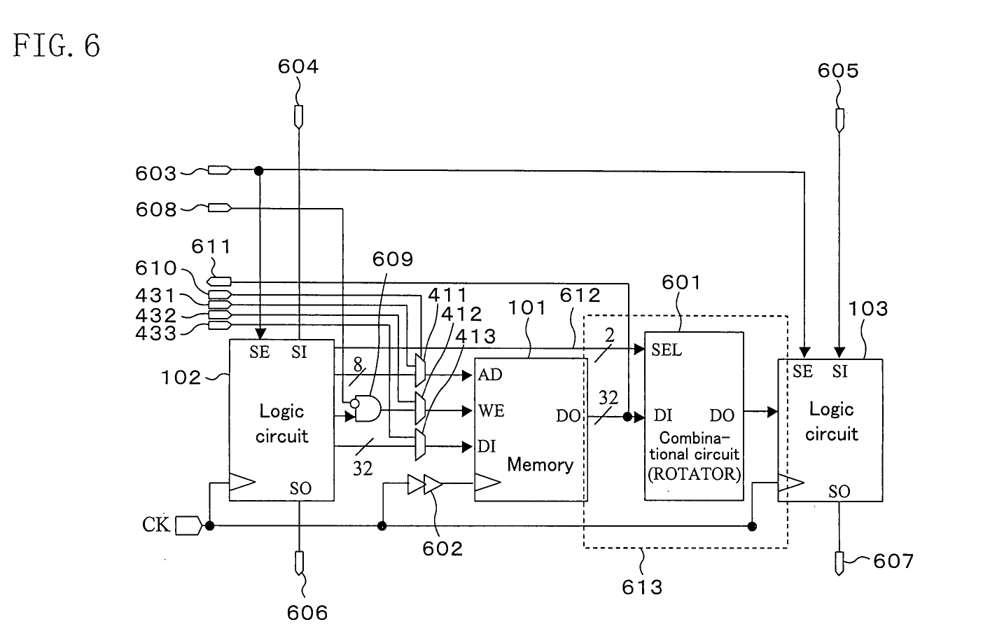

FIG. 6 illustrates an exemplary semiconductor integrated circuit according to a second embodiment of the present invention. In the second embodiment, at-speed test of the interface (input and output) of a memory 101 included in the semiconductor integrated circuit shown in FIG. 6 will be discussed.

In FIG. 6, the memory 101 is controlled from a logic circuit 102 and an output from the memory 101 is captured into a logic circuit 103 by way of a combinational circuit 601.

A clock signal CK serves as a clock signal for the memory 101 and other blocks. As a clock for the memory 101, a clock that is delayed behind a clock for the logic circuits 102 and 103 by a delay circuit 602 is input.

A scan-enable signal SE is applied to a SE terminal 603 from an external device. The scan-enable signal SE applied to the SE terminal 603 is supplied to the logic circuits 102 and 103. When the value of the scan-enable signal SE is “1”, a shift operation is performed, by which set values for the logic circuits 102 and 103 are externally input into shift-in terminals 604 and 605, while values stored in the logic circuits 102 and 103 are output from shift-out terminals 606 and 607 for comparison with expected values. When the value of the scan-enable signal SE is “0”, a capture operation is performed, by which the memory 101 operates in accordance with the value of the logic circuit 102, while, in the case of a read operation, an output from the memory 101 is captured into the logic circuit 103 via the combinational circuit 601.

A signal that indicates scan test mode is applied to a scan test mode terminal 608. A write inhibit circuit 609 is a circuit for inhibiting a write during scan test mode. The scan test mode terminal 608 takes “0” during normal operation to allow a write to the memory 101. During scan test mode, the scan test mode terminal 608 takes “1” to prohibit a write to the memory 101.

A signal that indicates memory test mode is applied to a memory test mode terminal 610 from an external device. The signal applied to the memory test mode terminal 610 is supplied to selectors 411, 412, and 413. At the time of memory testing or memory initialization, memory access signals AD, WE, and DI are applied from external terminals 431, 432 and 433 to the memory 101 through the selectors 411, 412, and 413. At the time of a write operation, a value for the memory 101 is established, while at the time of a read operation, output data of the memory 101 which is output from an external terminal 611 is compared with an expected value.

The memory access signals AD, WE, and DI are respectively an address signal AD, a write-enable signal WE, and a data input signal DI for the memory 101. When the write-enable signal WE takes “1”, data is written into the memory 101, and when the write-enable signal WE takes “0”, data is read from the memory 101. In this embodiment, the address signal AD has a width of 3 bits and the memory 101 is a memory of 8 words x 32 bits.

A data output signal DO from the memory 101 is a value which is read in accordance with a signal applied to the memory 101. The read value is captured into the logic circuit 103 via the combinational circuit 601 during a capture operation.

The combinational circuit 601 modifies the data which has been input to its DI terminal, according to an input 612 to its SEL terminal and then outputs the modified data from its DO terminal. More specifically, the combinational circuit 601, functioning as a rotator, outputs, from the DO terminal, DI[31:0], {DI[23:0], DI[31,24]}, {DI[15:0], DI[31,16]}, or {DI[7:0], DI[31,8]}, when the value of the signal 612 that is input to the SEL terminal is 2′b00 (indicating that the value has 2-bit width and is 00 in binary notation), 2′b01, 2′b10, or 2′b11.

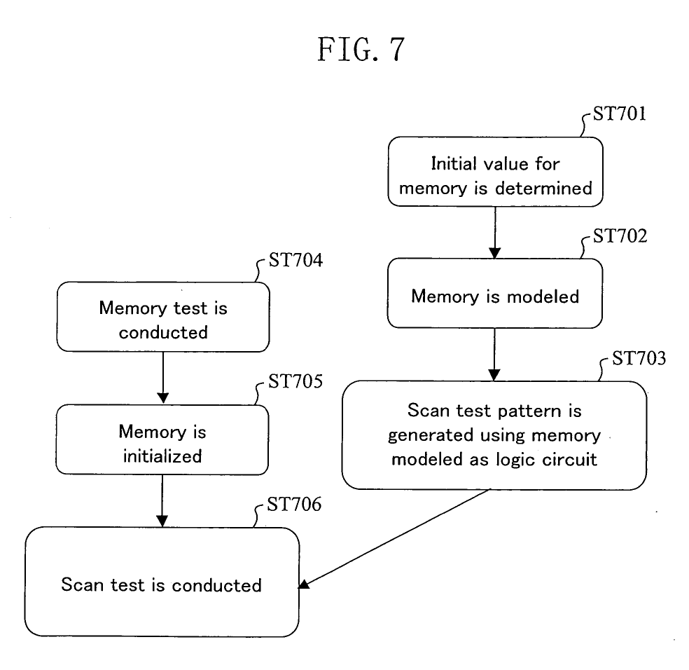

FIG. 7 is a flow chart indicating how to conduct the memory-interface actual-operation test according to the second embodiment of the present invention.

Step ST701 is a step for determining an initial value stored in the memory when the memory is modeled. Step ST702 is a step for performing modeling of the memory. In this step, the memory 101 shown in FIG. 6 is modeled into a combinational circuit. Step ST703 is a step for generating a scan test pattern for the modeled memory and a logic circuit. Step ST704 is a step for conducting a memory test, in which testing of the memory cells of the memory 101 or the like is performed. Step ST705 is a step for performing memory initialization. In steps ST705 and ST704, a value that corresponds to the initial value for the memory determined in step ST701 is established. Step ST706 is a step for carrying out a scan test, in which the scan test pattern created in step ST703 is executed to perform a memory interface test.

(Step ST701 for Determining Initial Value for Memory)

Step ST701 includes a step for determining an initial value that the memory 101 takes after the memory test in step ST704 is performed, and a step for determining a set value for optimally conducting the test, in step ST705, of the combinational circuit 601 connected to the memory 101.

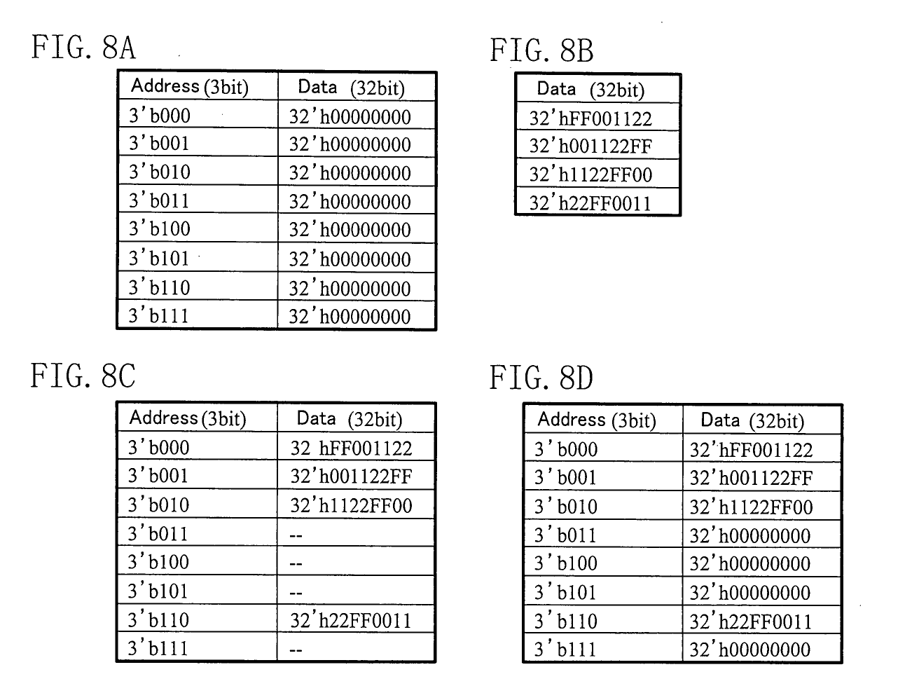

In a normal memory test, the entire regions are often set at the same value when the memory test is complete. In this embodiment, as shown in FIG. 8(a), all of the regions are initialized to a value of 32′h00000000 (which indicates that the value has 32-bit width and is 00000000 in hexadecimal notation). This value is the initial value for the memory 101 after the completion of the memory test.

Next, a virtual combinational circuit 613 in the semiconductor integrated circuit is defined, in which the logic circuit 103 reachable by a signal which is output from the data output terminal DO of the memory 101 is the end point and the data output terminal DO of the memory 101 and the select signal SEL of the combinational circuit 610 are the start points, and test patterns that enable the combinational circuit 601 and the logic circuit 103 to be tested optimally are determined. In this embodiment, the combinational circuit 601 is a rotator circuit and four patterns shown in FIG. 8(b) are used as the test patterns in order to test byte-by-byte data selection and 1-to-0 or 0-to-1 transitions of all of the bits. Next, the location of the initial value on the memory is determined as shown in FIG. 8(c) in order to test 1-to-0 or 0-to-1 transitions in an input signal to the memory 101, that is, in order to test a 1-to-0 or 0-to-1 transition of each bit of the address signal AD. By these steps, the initial value of the memory in terms of the test is set as shown in FIG. 8(c). In FIG. 8(c), the regions having a data value indicated with the mark “ ” may take any value in terms of the test, and therefore the initial value in the memory test may be reused in these regions, thereby enabling the time required for the memory initialization to be reduced. This is particularly effective in a large capacity memory, because an initialization region in the memory in terms of test is smaller than the memory capacity.

By the step ST701, the initial value of the memory finally becomes as shown in FIG. 8(d).

(Step ST702 for Memory Modeling)

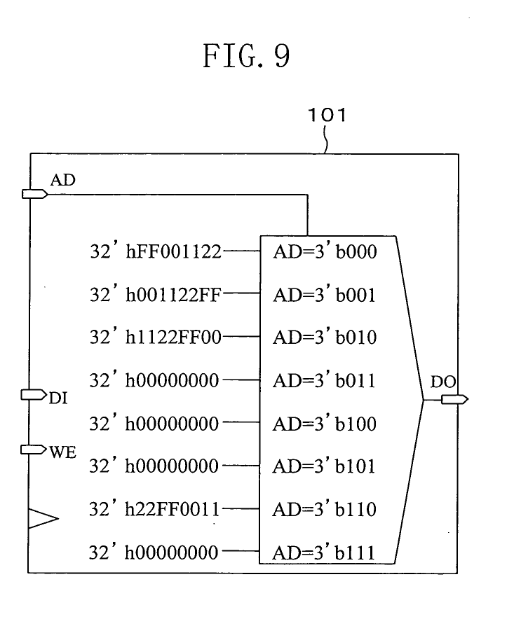

In the exemplary semiconductor integrated circuit of FIG. 6, the clock applied to the memory 101 is delayed by the delay circuit 602 behind the clock applied to the logic circuits 102 and 103. Therefore, the memory 101 can be modeled based on the assumption that the clock terminal does not affect the operation in terms of the clock edges. Also, in a case where data is not written into the memory 101 during scan testing, the memory 101 can be modeled, assuming that the terminals WE and DI also do not affect the operation. Finally, as shown in FIG. 9, the memory 101 can be modeled into a combinational circuit in which data according to the terminal AD is output from the terminal DO.

(Step ST703 for Generating Scan Test Pattern Using Modeled Memory)

In the semiconductor integrated circuit of FIG. 6, the memory 101 of FIG. 6 is replaced with the memory 101 shown in FIG. 9 and a scan test pattern is generated. In this case, if the circuits other than the memory 101 are of a full scan test design, then the modeled semiconductor integrated circuit is also of a full scan test design, and pattern generation is possible with a conventional scan test tool. Accordingly, even in a case where a tool compatible with partial scan tests is used, it is possible to reduce test-pattern generation time.

(Step ST704 for Testing Memory)

During a memory test, the memory test mode terminal 610 is set to “1”, and a write or a read is performed by applying the memory access signals AD, WE and DI from the external terminals 431, 432, and 433 through the selectors 411, 412, and 413 or by capturing a value at the external terminal 611, whereby not only the wiring or transistors are inspected for defects, but also relation between values retained in adjacent memory cells, and a read or write sequence are tested. By this step, the memory 101 is set to the value shown in FIG. 8(a).

Generally, delay in output from a memory is defined by relation between the edges of a clock and a sense amplifier that captures output from the memory cells at timing generated in the memory based on the clock edges, and it is examined in a memory test whether an output from each memory cell is produced in time for the timing at which the sense amplifier captures the output. Therefore, the output delay does not vary among read addresses. Accordingly, when at-speed test is performed in the scan test in step ST706, which will be described later, accesses to all of the addresses do not need to be verified.

(Step ST705 for Initializing Memory)

As in the case of the memory test, the memory test mode terminal 610 is set to “1”, and the memory access signals AD, WE and DI are applied from the external terminals 431, 432, and 433 through the selectors 411, 412, and 413, whereby the values shown in FIG. 8(c) are written. By this step, the memory 101 is set to the values shown in FIG. 8(d).

(Step ST706 for Performing Scan Test)

During a scan test, the memory test mode terminal 610 is set to “0” and a signal from the logic circuit 102 is selected by the selectors 411, 412, and 413, while at the same time the scan mode signal 608 is set to “1” to inhibit a write to the memory 101.

The SE terminal 603 is set to “1”, and set values for the logic circuits 102 and 103 are externally input into the shift-in terminals 604 and 605, while values stored in the logic circuits 102 and 103 are output from the shift-out terminals 606 and 607 for comparison with expected values. When the SE terminal 603 is “0”, a capture operation is performed, by which the memory 101 is operated according to the value of the logic circuit 102, while in the case of a read operation, an output from the memory 101 is captured into the logic circuit 103 by way of the combinational circuit 601. These operations are repeated, thereby verifying the memory interface.

As described above, in the second embodiment, in addition to the first embodiment, values established in the memory test are used in the initialization of the memory or the memory initialization is directly established without a scan test, whereby test time for the initialization can be reduced in the case of a large capacity memory as well. Then, if just the minimum number of initial values to be directly established is set appropriately, the actual operation of the memory interface of the combinational circuit connected to the memory can be tested optimally without performing a write to the memory during the memory interface test. Furthermore, by operating the memory interface at the actual speed, it is possible to perform an actual operation speed test.

Also, if write operations are inhibited and the memory is modeled into a combinational circuit, it is possible to generate, with a conventional full scan test technique, a test pattern between an output from the memory and the normal logic that receives the value, thereby making it possible to verify the actual operation of the memory interface even with an existing test tool. Moreover, even with a latest tool, it is possible to reduce pattern generation time by not considering write operations.

In a pipeline in a microprocessor, in particular, an address retention circuit for retaining an address to a memory is necessary, not for reasons of operation of the memory, but due to extension of the pipeline. Therefore, a storage element for retaining a control signal to be applied to the memory has to be provided immediately before the memory. However, in many cases, the clock applied to the memory is a delayed clock in order to reduce the number of unnecessary cycles. Also, when cycles have enough space, a memory and a combinational circuit are often designed in such a manner that the combinational circuit is inserted at the output side of the memory within the same cycle, in which case this embodiment is highly effective.

Verification of the terminals WE and DI that are not verified during scan testing can be confirmed by executing a simple normal-operation test-pattern (writing of data 0 into all bits and writing of data 1 into all bits), and thus causes no critical problem. Alternatively, if a storage element is inserted between the selectors 411, 412 and 413 for signals for memory testing and the memory 101 so that a circuit is shared between the inserted storage element and the memory 101 during normal operation and memory testing, then the verification can be performed by a write test conducted in the memory test.

In the semiconductor integrated circuit of the second embodiment, the write inhibit circuit 609 for inhibiting a write to the memory 101 during scan testing is used, but this is not particularly an indispensable circuit. If a scan test pattern generation tool creates a scan test pattern, in which no write operation is performed, similar effects are achievable. Also, if a scan pattern for performing a write operation after the execution of the scan test pattern in which no write operation is performed is added, it is possible to omit a normal-operation test pattern for confirming a write operation after the scan test pattern.

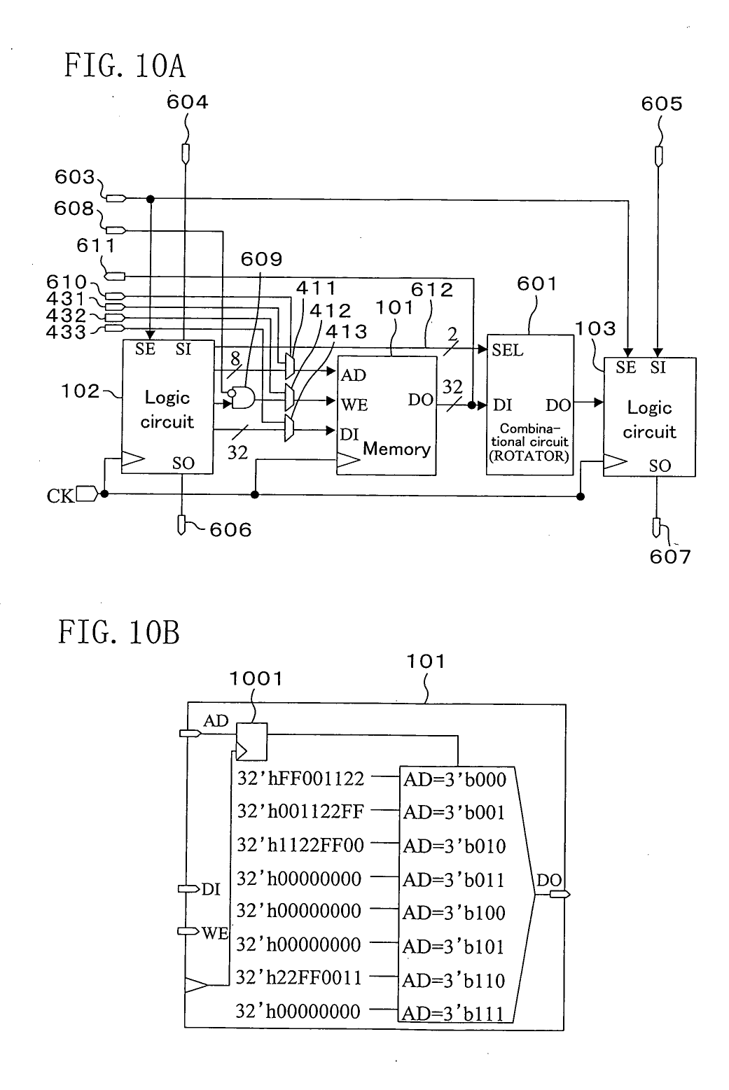

Moreover, in the semiconductor integrated circuit of the second embodiment, the clock applied to the memory 101 is the delayed clock that passes through the delay circuit 602. In the case of a semiconductor integrated circuit shown in FIG. 10(a), in which a clock that is input to logic circuits 102 and 103 is input to a memory 101, the memory 101 can be modeled as shown in FIG. 10(b). In this case, since a storage element 1001 existing in the modeled memory is not a scan-testing-ready device, a partial scan testing technique is necessary. However, the value to be stored in the memory 101 is not changed, but a control signal to the memory 101 is only latched, and a pattern for testing a combinational circuit 601 is stored in advance in the memory 101. Therefore, it is possible to reduce the time required for scan test pattern generation.

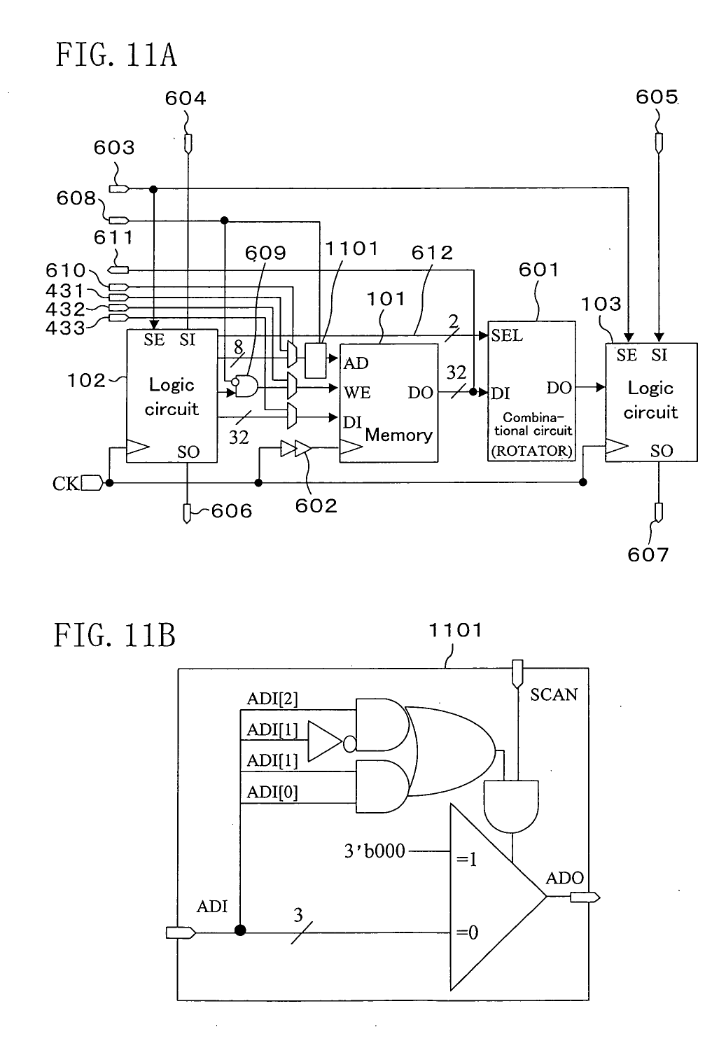

In a case where a memory test is performed after a scan test, or in a case where a memory test is performed but a value to be retained in the memory after the completion of the memory test is unknown, step ST704 is omitted, such that the memory initialization is performed only in step ST705. In this case, if an address conversion circuit 1101 is inserted as shown in FIG. 11(a) in order to suppress capturing of an indeterminate value occurring when an access to a non-initialized region occurs, the same effects as those obtainable in this embodiment are attained. FIG. 11(b) illustrates an exemplary configuration of the address conversion circuit 1101.

Furthermore, as described in the second embodiment, in a case where the number of initial values for a memory, required to test a combinational circuit, is small, if a memory that stores initial values beforehand in its specific non-volatile region, such as a ROM having initial values in a region thereof or a RAM having initial values in a test ROM region thereof, is used, the same effects as those obtainable in this embodiment are attained.

In step ST701, a pattern to be stored in the memory is prepared in order to test byte-by-byte data selection and 1-to-0 or 0-to-1 transitions of all of the bits. However, it is possible to verify a 1-to-0 or 0-to-1 transition of each bit in terms of stack fault, or verify a critical path in terms of speed fault. Moreover, pattern generation may be performed for a virtual block 613 using an ATPG tool.

The semiconductor integrated circuit described in the second embodiment includes the write inhibit circuit 609 that inhibits a write during scan testing. Alternatively, if a scan test pattern, in which no write is performed to the memory during BIST test or scan test, is prepared by a test sequence generation method by supplying a write inhibit instruction to a test sequence generation tool and the prepared scan test pattern is used instead of the write inhibit circuit 609, it is also possible to model the memory in a similar manner.

In the foregoing embodiments, the memory BIST has been described in distinction from the memory testing, and the logic BIST has been described in distinction from the scan testing. However, BIST is a technique based on memory-testing or scan-testing technology to which self-diagnosis function has been added. Thus, these respective two tests have common techniques and effects, except for differences in hardware such as a pattern generation circuit necessary for self-diagnosis and a compression circuit, restrictions on test patterns that the pattern generation circuit generates, and the constraint that the compression circuit cannot capture an indeterminate value.

In the test methods of the present invention, a process step for initializing a memory circuit is provided, so that a value for the memory circuit is determined before the start of the test, whereby an indeterminate value is not output from the memory circuit during the test, which allows the output from the memory circuit to be captured as it is and used for the test. The inventive methods are thus effective, e.g., as built-in self-tests, in which a compression circuit is used, and are particularly suited to testing the actual operation of the interface (input terminal/output terminal) of a memory circuit. In the test methods using scan testing, a memory-circuit initialization step is also provided so that values for minimum necessary regions in the entire memory circuit are determined before the start of the testing. Then, the time required to establish the memory values is reduced, which results in a reduction in the test costs of the semiconductor integrated circuit.

1. A method for testing a semiconductor integrated circuit that includes a memory circuit provided between a first storage element and a second storage element, the method comprising the steps of:
(a) initializing the memory circuit;
(b) supplying a test pattern to the first storage element;
(c) supplying a memory access signal, which corresponds to the test pattern supplied to the first storage element, to the memory circuit through a path that is used in normal operation;
(d) capturing a value output from the memory circuit in response to the memory access signal, into the second storage element through a path that is used in normal operation; and
(e) comparing the value captured into the second storage element with an expected value.

2. The method of claim 1, wherein the semiconductor integrated circuit further includes a pseudo-random pattern generation circuit and a compression circuit;
in the step (b), a random pattern produced from the pseudo-random pattern generation circuit is supplied to the first storage element as the test pattern; and
in the step (e), the value captured into the second storage element is compressed by the compression circuit and a signal resulting from the compression is compared with the expected value.

3. The method of claim 1, wherein the first and second storage elements are storage elements capable of scanning;
in the step (b), the test pattern is supplied to the first storage element by a shift operation; and
in the step (e), the value captured into the second storage element is read by a shift operation, and the read value is compared with the expected value.

4. The method of claim 2, wherein the memory circuit is a multiport memory having a write port and a read port separately; and
the semiconductor integrated circuit further includes an address conversion circuit, which is provided between the first storage element and the memory circuit and prevents, during a test, a write and a read from being performed simultaneously to and from an identical address in the write and read ports of the memory circuit.

5. The method of claim 1, wherein the semiconductor integrated circuit further includes an address conversion circuit, which is provided between the first storage element and the memory circuit and limits accesses made to the memory circuit in the steps (c) and (d) to a given region; and
in the step (a), of regions in the memory circuit, the region limited by the address conversion circuit is initialized.

6. The method of claim 1, wherein in the step (b), a pattern for performing a write to the memory circuit is supplied to the first storage element as the test pattern.

7. The method of claim 1, wherein the semiconductor integrated circuit further includes a write inhibit circuit, which is provided between the first storage element and the memory circuit and inhibits any writes to the memory circuit in the steps (b) through (e).

8. The method of claim 1, wherein the initialization of the memory circuit in the step (a) is performed in a memory test.

9. The method of claim 1, wherein the step (a) includes:
the step (a1) of performing a memory test, and
the step (a2) of establishing a value for a region in the memory circuit.

10. The method of claim 8, wherein the semiconductor integrated circuit further includes a memory BIST circuit for testing the memory circuit, and
the memory test is performed using the memory BIST circuit.

11. The method of claim 9, wherein the semiconductor integrated circuit further includes a memory BIST circuit for testing the memory circuit, and
the memory test is performed using the memory BIST circuit.

12. The method of claim 1, wherein the memory circuit includes a non-volatile region, and
in the step (a), an initial value is stored in the non-volatile region.

13. The method of claim 1, wherein in the step (a), of test sequences prepared for a combinational circuit, whose start point includes a data output terminal of the memory circuit and whose end point is a storage element reachable by a signal which is output from the data output terminal of the memory circuit, a test sequence assigned to the data output terminal is used as a value to which the memory circuit is initialized.

14. The method of claim 1, wherein process steps performed in the steps (b) through (e) are performed at an actual operation speed of the semiconductor integrated circuit.

15. The method of claim 7, further comprising the steps of:
(f) modeling the memory circuit into a combinational sequential circuit, and
(g) generating a test pattern using the modeled memory circuit,
wherein in the step (b), the test pattern generated in the step (g) is supplied to the first storage element.

16. The device of claim 1, further comprising the steps of:
(f) modeling the memory circuit into a combinational sequential circuit, and
(g) generating, using the modeled memory circuit, a test pattern that does not include a write to the memory circuit,
wherein in the step (b), the test pattern generated in the step (g) is supplied to the first storage element.

17. The device of claim 15, wherein in the step (f), the memory circuit is modeled into a combinational circuit.

18. The device of claim 16, wherein in the step (f), the memory circuit is modeled into a combinational circuit.
